(19) United States
(12) Patent Application Publication
(10) Pub. No.: US 2026/0223324 A1
(43) Pub. Date: Jul. 30, 2026

(54) WATER COOLING HEAT SINK

(71) Applicant: FURUKAWA ELECTRIC CO., LTD., Tokyo (JP)

(72) Inventors: Yasuhiro UCHIMURA, Tokyo (JP); Hiroshi KATO, Tokyo (JP); Hirofumi AOKI, Tokyo (JP)

(73) Assignee: FURUKAWA ELECTRIC CO., LTD., Tokyo (JP)

(21) Appl. No.: 19/573,380

(22) Filed: Mar. 20, 2026

Related U.S. Application Data
(63) Continuation of application No. PCT/JP2025/031053, filed on Sep. 3, 2025.

(30) Foreign Application Priority Data
Sep. 5, 2024 (JP) 2024-153283

(51) Int. Cl. H05K 7/20; G06F 1/20

(52) U.S. Cl. CPC H05K 7/20272; G06F 1/20; H05K 7/20254; H05K 7/20472

(57) ABSTRACT

A water cooling heat sink includes a pipe group including pipes having a contact portion thermally contacting a memory and extending linearly, a first bent portion connected to one end of the contact portion, and a second bent portion connected to the other end of the contact portion, in which a height of a connecting portion between one end of the first bent portion and the contact portion differs from a height of the other end of the first bent portion, and/or a height of a connecting portion between one end of the second bent portion and the contact portion differs from a height of the other end of the second bent portion; an inlet-side manifold connected to the other ends of the first bent portions and supplying a coolant; and an outlet-side manifold connected to the other ends of the second bent portions and discharging the coolant.

### CROSS REFERENCE TO RELATED APPLICATIONS

This application claims the benefit of priority to Japanese Patent Application No. 2024-153283 filed on September 5, 2024 and is a Continuation Application of PCT Application No. PCT/JP2025/031053 filed on September 3, 2025. The entire contents of each application are hereby incorporated herein by reference.

### BACKGROUND OF THE INVENTION

### 1. Field of the Invention

The present disclosure relates to a water cooling heat sink.

### 2. Description of the Related Art

With the increase in performance of CPUs, heat generation of a memory serving as a storage device supporting the CPUs is also increasing.

Generally, the memory is cooled by ventilation from a system fan of the device in which the memory is mounted. However, due to an increase in heat generation of the memory, the temperature of the memory cannot be sufficiently lowered only by cooling of ventilation in many cases.

The memory is mounted on a motherboard as a substrate in the form of a memory module. A plurality of memory modules is erected on the motherboard at extremely narrow intervals. Therefore, a heat sink for cooling the memory cannot be easily attached, and there are limited means for improving the cooling performance of the memory by air cooling. Therefore, as disclosed in U.S. Published Patent Application Publication, No. 2024/237269, Specification, etc., measures to improve the cooling performance of the memory by using a water cooling heat sink have been studied.

However, in a heat sink as disclosed in U.S. Published Patent Application Publication, No. 2024/237269, Specification, constituent members such as a manifold that distributes a coolant to pipes of the heat sink, a supply hose that supplies the coolant to the manifold, and a discharge hose that discharges the coolant from the manifold are disposed on a substrate. Therefore, the degree of freedom in design for mounting the constituent members on the substrate is limited.

### SUMMARY OF THE INVENTION

An object of the present disclosure is to provide a water cooling heat sink capable of improving the degree of freedom in the installation position.

### Means for Solving the Problems

[1] A water cooling heat sink for cooling a memory, the water cooling heat sink including: a pipe group including a plurality of pipes having a contact portion that thermally contacts the memory provided on a memory module and extends linearly, a first bent portion connected to one end of the contact portion, and a second bent portion connected to the other end of the contact portion, in which a height of a connecting portion between one end of the first bent portion and the contact portion differs from a height of the other end of the first bent portion, and/or a height of a connecting portion between one end of the second bent portion and the contact portion differs from a height of the other end of the second bent portion; an inlet-side manifold that is connected to the other ends of the first bent portions of the pipe group and supplies a coolant to the pipe group; and an outlet-side manifold that is connected to the other ends of the second bent portions of the pipe group and discharges the coolant from the pipe group.

[2] The water cooling heat sink according to [1] above, in which the first bent portion is bent away from a substrate on which the water cooling heat sink is installed.

[3] The water cooling heat sink according to [1] or [2] above, in which the inlet-side manifold is connected to the pipe group at a position away from a substrate on which the water cooling heat sink is installed.

[4] The water cooling heat sink according to any one of [1] to [3] above, in which the second bent portion is bent away from a substrate on which the water cooling heat sink is installed.

[5] The water cooling heat sink according to any one of [1] to [4] above, in which the outlet-side manifold is connected to the pipe group at a position away from a substrate on which the water cooling heat sink is installed.

[6] The water cooling heat sink according to any one of [1] to [5] above, further including one or more thermal conductive sheets provided on a surface of the contact portion of the pipe group.

[7] The water cooling heat sink according to any one of [1] to [6] above, in which a shortest distance M1 from a substrate on which the water cooling heat sink is installed to a portion of the inlet-side manifold closest to the substrate is greater than a shortest distance L1 from the substrate to a portion of the memory most distant from the substrate.

[8] The water cooling heat sink according to any one of [1] to [7] above, in which a shortest distance M2 from a substrate on which the water cooling heat sink is installed to a portion of the outlet-side manifold closest to the substrate is greater than a shortest distance L1 from the substrate to a portion of the memory most distant from the substrate.

[9] The water cooling heat sink according to any one of [1] to [8] above, in which a shortest distance M1 from a substrate on which the water cooling heat sink is installed to a portion of the inlet-side manifold closest to the substrate is greater than a shortest distance L2 from the substrate to a portion of the memory module most distant from the substrate.

The water cooling heat sink according to any one of [1] to [9] above, in which a shortest distance M2 from a substrate on which the water cooling heat sink is installed to a portion of the outlet-side manifold closest to the substrate is greater than a shortest distance L2 from the substrate to a portion of the memory module most distant from the substrate.

### Effects of the Invention

According to the present disclosure, it is possible to provide a water cooling heat sink capable of improving the degree of freedom in the installation position.

### BRIEF DESCRIPTION OF THE DRAWINGS

FIG. 1 is a perspective view showing an example of a water cooling heat sink according to an embodiment.

FIG. 2 is an exploded perspective view showing the example of the water cooling heat sink according to the embodiment.

FIG. 3 is an enlarged schematic view for explaining a relationship between distances of the water cooling heat sink according to the embodiment.

FIG. 4 is another enlarged schematic view for explaining a relationship between distances of the water cooling heat sink according to the embodiment.

### DETAILED DESCRIPTION OF THE EXAMPLE EMBODIMENTS

Hereinafter, a detailed description will be given based on an embodiment.

As a result of intensive studies on a water cooling heat sink, the present inventors have found that the degree of freedom in the installation position can be improved by each disposing the inlet-side manifold and the outlet-side manifold of the water cooling heat sink at a predetermined position, and have completed the present disclosure based on such findings.

A water cooling heat sink according to the embodiment is a water cooling heat sink for cooling a memory, the water cooling heat sink includes a pipe group including a plurality of pipes having a contact portion that thermally contacts the memory provided on a memory module and extends linearly, a first bent portion connected to one end of the contact portion, and a second bent portion connected to the other end of the contact portion, in which a height of a connecting portion between one end of the first bent portion and the contact portion differs from a height of the other end of the first bent portion, and/or a height of a connecting portion between one end of the second bent portion and the contact portion differs from a height of the other end of the second bent portion; an inlet-side manifold that is connected to the other ends of the first bent portions of the pipe group and supplies a coolant to the pipe group; and an outlet-side manifold that is connected to the other ends of the second bent portions of the pipe group and discharges the coolant from the pipe group.

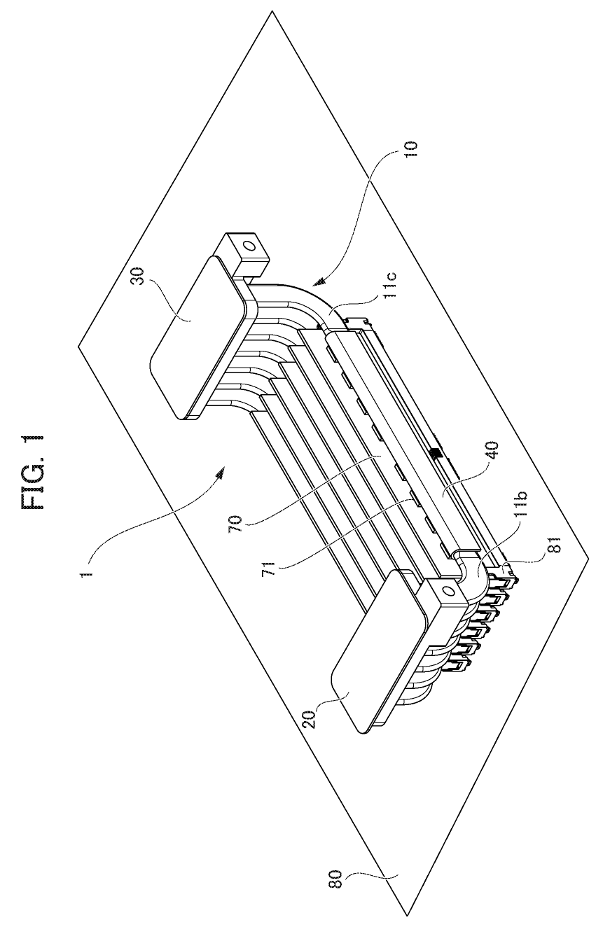

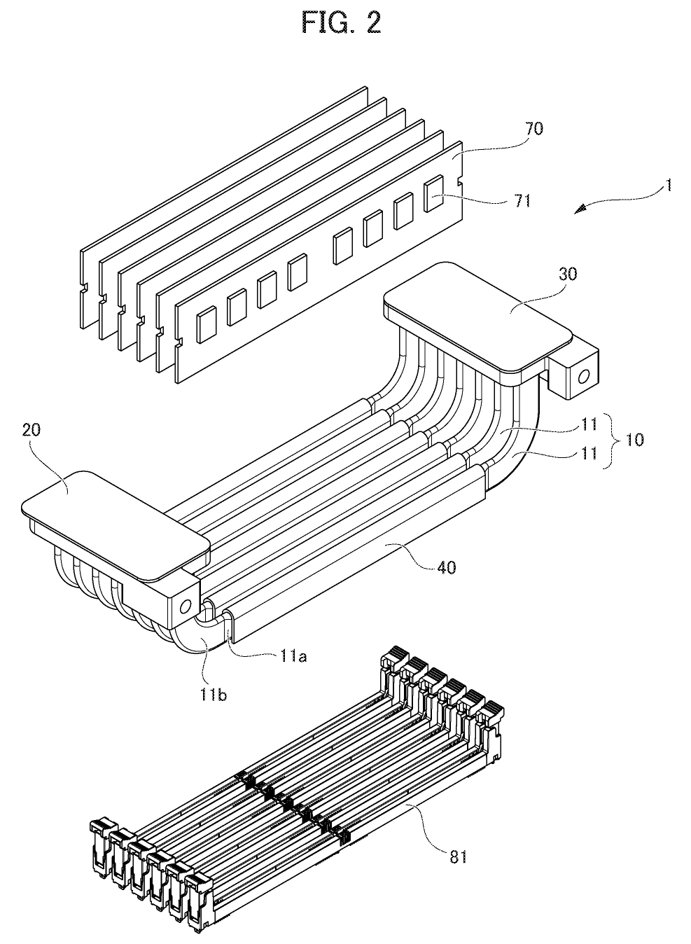

FIG. 1 is a perspective view showing an example of the water cooling heat sink according to the embodiment. FIG. 2 is an exploded perspective view showing the example of the water cooling heat sink according to the embodiment.

As shown in FIGS. 1 and 2, a water cooling heat sink 1 according to the embodiment includes a pipe group 10, an inlet-side manifold 20, and an outlet-side manifold 30. The water cooling heat sink 1 is a member for cooling a memory 71, and a coolant (not shown) flows through the internal space of the water cooling heat sink 1. The water cooling heat sink 1 is provided on a substrate 80 such as a motherboard.

The pipe group 10 constituting the water cooling heat sink 1 includes a plurality of pipes 11. A memory module 70 including the memories 71 is provided between the plurality of pipes 11, that is, in a gap between a pipe 11 and another pipe 11 adjacent thereto, and is inserted into a socket 81 for the memory module 70 provided on the substrate 80 so that one main surface of the memory module 70 faces the pipe 11 and the other main surface of the memory module 70 faces the other pipe 11 adjacent thereto.

The memory 71 is provided on a main surface of the memory module 70. The memory 71 on the memory module 70 is in direct contact with a contact portion 11a of the pipe 11, or is in contact with the contact portion 11a via a thermal conductive sheet 40 described later, and thereby is in thermal contact with the contact portion 11a of the pipe group 10.

Here, an example in which the memory module 70 includes a plurality of memories 71 is shown, but the number of the memories 71 installed is not particularly limited, and for example, the memory module 70 may include only one memory 71. The number of the pipes 11 is set as appropriate depending on the number of the memory modules 70 installed.

Each of the plurality of pipes 11 includes a contact portion 11a, a first bent portion 11b, and a second bent portion 11c.

The contact portion 11a extends linearly. The contact portion 11a is in direct contact with the memory 71 on the memory module 70, or is in contact with the memory 71 via the thermal conductive sheet 40 described later, and thereby is in thermal contact with the memory 71. The contact portion 11a is longer than the memory module 70. The bottom surface of the contact portion 11a is fixed to the substrate 80 via the socket 81.

The first bent portion 11b is connected to one end of the contact portion 11a. Here, an example in which the shape of the first bent portion 11b is a curved shape is illustrated, but the shape of the first bent portion 11b is not particularly limited.

The second bent portion 11c is connected to the other end of the contact portion 11a. Here, an example in which the shape of the second bent portion 11c is a curved shape is illustrated, but the shape of the second bent portion 11c is not particularly limited.

In the pipe 11, the height of the connecting portion between one end of the first bent portion 11b and the contact portion 11a differs from the height of the other end of the first bent portion 11b, and/or the height of the connecting portion between one end of the second bent portion 11c and the contact portion 11a differs from the height of the other end of the second bent portion 11c.

The height from the connecting portion between one end of the first bent portion 11b and the contact portion 11a to the other end of the first bent portion 11b is preferably 10 mm or more and 100 mm or less. The height from the connecting portion between one end of the first bent portion 11b and the contact portion 11a to the other end of the first bent portion 11b is the height from the bottom portion of the connecting portion to the other end (upper end) of the first bent portion 11b. When the above height is 10 mm or more, the degree of freedom in the installation position of the water cooling heat sink 1 can be sufficiently improved. When the above height is 100 mm or less, the water cooling heat sink 1 can be made compact.

The height from the connecting portion between one end of the second bent portion 11c and the contact portion 11a to the other end of the second bent portion 11c is preferably 10 mm or more and 100 mm or less. The height from the connecting portion between one end of the second bent portion 11c and the contact portion 11a to the other end of the second bent portion 11c is the height from the bottom portion of the connecting portion to the other end (upper end) of the second bent portion 11c. When the above height is 10 mm or more, the degree of freedom in the installation position of the water cooling heat sink 1 can be sufficiently improved. When the above height is 100 mm or less, the water cooling heat sink 1 can be made compact.

When the height of the connecting portion between one end of the first bent portion 11b and the contact portion 11a differs from the height of the other end of the first bent portion 11b, the first bent portion 11b is bent away from the substrate 80 on which the water cooling heat sink 1 is installed. When the height of the connecting portion between one end of the second bent portion 11c and the contact portion 11a differs from the height of the other end of the second bent portion 11c, the second bent portion 11c is bent away from the substrate 80 on which the water cooling heat sink 1 is installed.

From the viewpoint of thermal conductivity and the like, the pipe group 10 is preferably made of copper or a copper alloy.

The inlet-side manifold 20 constituting the water cooling heat sink 1 is connected to the other ends of the first bent portions 11b of the pipe group 10, and supplies the coolant to the plurality of pipes 11 of the pipe group 10. A supply hose (not shown) that supplies the coolant to the inlet-side manifold 20 is connected to the inlet-side manifold 20. As described above, the inlet-side manifold 20 is connected to the plurality of pipes 11 of the pipe group 10 at a position away from the substrate 80 on which the water cooling heat sink 1 is installed. For example, as shown in FIGS. 1 and 2, the inlet-side manifold 20 is connected to all of the pipes 11 constituting the pipe group 10.

As described above, since the inlet-side manifold 20 constituting the water cooling heat sink 1 is disposed at a position higher than the height of the connecting portion between the one end of the first bent portion 11b and the contact portion 11a and further away from the substrate 80 than the contact portion 11a, the degree of freedom in the installation position of the water cooling heat sink 1 can be improved. In particular, since the inlet-side manifold 20 is not disposed on the substrate 80 and a space corresponding to the volume of the inlet-side manifold 20 can be secured on the substrate 80, the degree of freedom in designing the inlet-side manifold can be improved.

From the viewpoint of thermal conductivity and the like, the inlet-side manifold 20 is preferably made of copper or a copper alloy.

The pipe group 10 and the inlet-side manifold 20 are preferably joined by brazing or welding, and more preferably joined by laser welding from the viewpoint of excellent rigidity.

The outlet-side manifold 30 constituting the water cooling heat sink 1 is connected to the other ends of the second bent portions 11c of the pipe group 10, and discharges the coolant from the plurality of pipes 11 of the pipe group 10. A discharge hose (not shown) that discharges the coolant from the outlet-side manifold 30 is connected to the outlet-side manifold 30. As described above, the outlet-side manifold 30 is connected to the plurality of pipes 11 of the pipe group 10 at a position away from the substrate 80 on which the water cooling heat sink 1 is installed. For example, as shown in FIGS. 1 and 2, the outlet-side manifold 30 is connected to all of the pipes 11 constituting the pipe group 10.

As described above, since the outlet-side manifold 30 constituting the water cooling heat sink 1 is disposed at a position higher than the height of the connecting portion between the one end of the second bent portion 11c and the contact portion 11a and further away from the substrate 80 than the contact portion 11a, the degree of freedom in the installation position of the water cooling heat sink 1 can be improved. In particular, since the outlet-side manifold 30 is not disposed on the substrate 80 and a space corresponding to the volume of the outlet-side manifold 30 can be secured on the substrate 80, the degree of freedom in designing the outlet-side manifold can be improved.

From the viewpoint of thermal conductivity and the like, the outlet-side manifold 30 is preferably made of copper or a copper alloy.

The pipe group 10 and the outlet-side manifold 30 are preferably joined by brazing or welding, and more preferably joined by laser welding from the viewpoint of excellent rigidity.

From the viewpoint of further improving the cooling performance, as shown in FIGS. 1 and 2, the water cooling heat sink 1 preferably further includes one or more thermal conductive sheets 40 provided on the surface of the contact portion 11a of the pipe group 10.

When the water cooling heat sink 1 includes the thermal conductive sheet 40, the thermal conductive sheet 40 is in direct contact with the memory 71 of the memory module 70 and the contact portion 11a of the pipe 11, and the memory 71 is in thermal contact with the contact portion 11a via the thermal conductive sheet 40. Since the thermal conductive sheet 40 efficiently conducts the heat of the memory 71 to the pipe group 10, the memory 71 can be favorably cooled.

From the viewpoint of further improving the cooling performance, the thermal conductive sheet 40 is preferably made of silicone rubber.

The number of the thermal conductive sheets 40 is set as appropriate depending on the number of pipes 11.

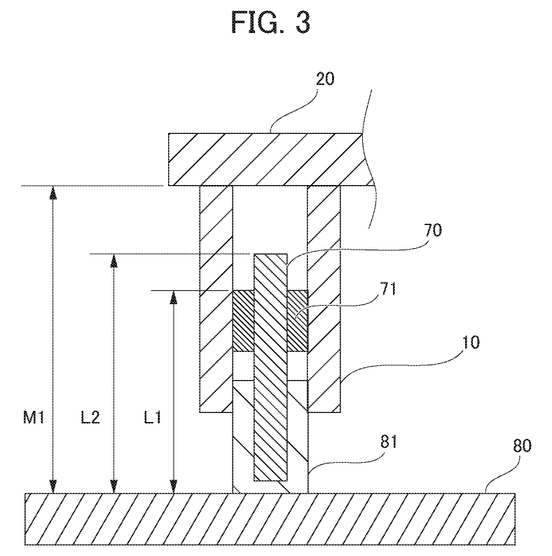

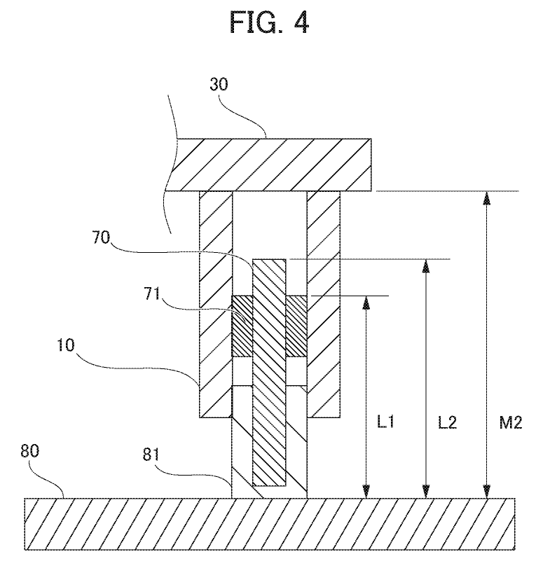

FIG. 3 is an enlarged schematic view for explaining the relationship between distances in the water cooling heat sink according to the embodiment. In FIG. 3 and FIG. 4 described later, the thermal conductive sheet 40 and the like are omitted for convenience.

As shown in FIG. 3, the shortest distance M1 from the substrate 80 to the portion of the inlet-side manifold 20 closest to the substrate 80 is preferably greater than the shortest distance L1 from the substrate 80 to the portion of the memory 71 most distant from the substrate 80. In FIG. 3, the shortest distance M1 corresponds to the height from the surface of the substrate 80 to the lower surface of the inlet-side manifold 20, and the shortest distance L1 corresponds to the height from the surface of the substrate 80 to the upper end of the memory 71. When the shortest distance M1 is greater than the shortest distance L1, the space secured on the substrate 80 is further increased, and thus the degree of freedom in design on the substrate 80 can be further improved.

The shortest distance M1 is more preferably greater than the shortest distance L2 from the substrate 80 to the portion of the memory module 70 most distant from the substrate 80. In FIG. 3, the shortest distance L2 corresponds to the height from the surface of the substrate 80 to the upper end of the memory module 70. When the shortest distance M1 is greater than the shortest distance L2, the space secured on the substrate 80 is further increased, and thus the degree of freedom in design on the substrate 80 can be further improved.

FIG. 4 is another enlarged schematic view for explaining the relationship between distances in the water cooling heat sink of the embodiment.

As shown in FIG. 4, the shortest distance M2 from the substrate 80 to the portion of the outlet-side manifold 30 closest to the substrate 80 is preferably greater than the shortest distance L1 from the substrate 80 to the portion of the memory 71 most distant from the substrate 80. In FIG. 4, the shortest distance M2 corresponds to the height from the surface of the substrate 80 to the lower surface of the inlet-side manifold 20. When the shortest distance M2 is greater than the shortest distance L1, the space secured on the substrate 80 is further increased, and thus the degree of freedom in design on the substrate 80 can be further improved.

The shortest distance M2 is more preferably greater than the shortest distance L2. When the shortest distance M2 is greater than the shortest distance L2, the space secured on the substrate 80 is further increased, and thus the degree of freedom in design on the substrate 80 can be further improved.

From the viewpoint of improving the degree of freedom in design on the substrate 80, at least one of the shortest distance M1 being greater than the shortest distance L1 or the shortest distance M2 being greater than the shortest distance L1 is preferably satisfied, and both of them are more preferably satisfied. From the viewpoint of further improving the degree of freedom in design on the substrate 80, at least one of the shortest distance M1 being greater than the shortest distance L2 or the shortest distance M2 being greater than the shortest distance L2 is preferably satisfied, and both of them are more preferably satisfied.

Since such a water cooling heat sink 1 can improve the degree of freedom in the installation position, the water cooling heat sink 1 is suitably used in a data center. As a result, a water cooling server with higher performance can be designed.

According to the embodiment described above, the inlet-side manifold and the outlet-side manifold of the water cooling heat sink are respectively disposed at a predetermined position, so that the degree of freedom in the installation position of the water cooling heat sink can be improved.

Although the embodiment has been described above, the present invention is not limited to the above embodiment, and various modifications can be made within the scope of the present disclosure, including all aspects encompassed by the concepts and claims of the present disclosure.

### REFERENCE SIGNS LIST

1 water cooling heat sink

10 pipe group

11 pipe

11a contact portion

11b first bent portion

11c second bent portion

20 inlet-side manifold

30 outlet-side manifold

40 thermal conductive sheet

70 memory module

71 memory

80 substrate

81 socket

What is claimed is:

1. A water cooling heat sink for cooling a memory, the water cooling heat sink comprising:
a pipe group comprising a plurality of pipes including a contact portion that thermally contacts the memory provided on a memory module and extends linearly, a first bent portion connected to one end of the contact portion, and a second bent portion connected to the other end of the contact portion, wherein a height of a connecting portion between one end of the first bent portion and the contact portion differs from a height of the other end of the first bent portion, and/or a height of a connecting portion between one end of the second bent portion and the contact portion differs from a height of the other end of the second bent portion;
an inlet-side manifold that is connected to the other ends of the first bent portions of the pipe group and supplies a coolant to the pipe group; and
an outlet-side manifold that is connected to the other ends of the second bent portions of the pipe group and discharges the coolant from the pipe group.

2. The water cooling heat sink according to claim 1, wherein the first bent portion is bent away from a substrate on which the water cooling heat sink is installed.

3. The water cooling heat sink according to claim 1, wherein the inlet-side manifold is connected to the pipe group at a position away from a substrate on which the water cooling heat sink is installed.

4. The water cooling heat sink according to claim 1, wherein the second bent portion is bent away from a substrate on which the water cooling heat sink is installed.

5. The water cooling heat sink according to claim 1, wherein the outlet-side manifold is connected to the pipe group at a position away from a substrate on which the water cooling heat sink is installed.

6. The water cooling heat sink according to claim 1, further comprising one or more thermal conductive sheets provided on a surface of the contact portion of the pipe group.

7. The water cooling heat sink according to claim 1, wherein a shortest distance M1 from a substrate on which the water cooling heat sink is installed to a portion of the inlet-side manifold closest to the substrate is greater than a shortest distance L1 from the substrate to a portion of the memory most distant from the substrate.

8. The water cooling heat sink according to claim 1, wherein a shortest distance M2 from a substrate on which the water cooling heat sink is installed to a portion of the outlet-side manifold closest to the substrate is greater than a shortest distance L1 from the substrate to a portion of the memory most distant from the substrate.

9. The water cooling heat sink according to claim 1, wherein a shortest distance M1 from a substrate on which the water cooling heat sink is installed to a portion of the inlet-side manifold closest to the substrate is greater than a shortest distance L2 from the substrate to a portion of the memory module most distant from the substrate.

10. The water cooling heat sink according to claim 1, wherein a shortest distance M2 from a substrate on which the water cooling heat sink is installed to a portion of the outlet-side manifold closest to the substrate is greater than a shortest distance L2 from the substrate to a portion of the memory module most distant from the substrate.
